(19) United States
(12) Patent Application Publication
(10) Pub. No.: US 2026/0093080 A1
(43) Pub. Date: Apr. 2, 2026

(54) Substrate embedded optical chiplet for integrated photonic interconnects

(71) Applicant: Marvell Asia Pte Ltd, Singapore (SG)

(72) Inventors: Kazin Simon Blacklow, Burlington, VT (US); Mark William Kuemerle, Essex Junction, VT (US); Sidney William Allman, Stittsville (ON); Carlos Macian Ruiz, Los Gatos, CA (US); Aatreya Chakravarti, Winooski, VT (US); Zachary Baldwin, Burlington, VT (US); Ting Zheng, San Jose, CA (US); Joshua F Dillon, Stowe, VT (US); John Edward Gregory, JR., Dummerston, VT (US); Wolfgang Sauter, Starksboro, VT (US); Samer Akiki, Redwood City, CA (US)

(21) Appl. No.: 19/071,793

(22) Filed: Mar. 6, 2025

Related U.S. Application Data
(60) Provisional application No. 63/576,003, filed on Jan. 9, 2023.
(60) Provisional application No. 63/562,582, filed on Mar. 7, 2024.

(51) Int. Cl. G02B 6/42; H10W 70/05; H10W 70/60; H10W 70/63; H10W 70/692

(52) U.S. Cl. CPC G02B 6/4278; G02B 6/4206; H10W 70/095; H10W 70/611; H10W 70/635; G02B 6/428; H10W 70/692

(57) ABSTRACT

An optoelectronic device includes: (a) a substrate having (i) a surface, and (ii) a recess formed in the substrate that extends from the surface into the substrate, (b) an integrated circuit (IC) chip facing the surface of the substrate, (c) an optical connector mounted on the substrate, and (d) an optical chiplet embedded within the recess of the substrate. The optical chiplet being configured to exchange (i) optical signals with the optical connector, and (ii) electrical signals with the integrated circuit (IC) chip, and to convert between the optical signals and the electrical signals.

### CROSS-REFERENCE TO RELATED APPLICATIONS

This application claims the benefit of U.S. Provisional Patent Application 63/562,582, filed Mar. 7, 2024, and the benefit of U.S. Provisional Patent Application 63/756,003, filed Feb. 7, 2025. The disclosures of these related applications are incorporated herein by reference.

### FIELD OF THE DISCLOSURE

The present invention relates generally to optoelectronic devices, and particularly to techniques for improving interfaces and connections between optical signals and electrical signals in optoelectronic devices.

### BACKGROUND

Optical communication systems are increasingly used to transmit large volumes of data at high speeds over long distances. As data transmission capacities continue to grow, there is a rising interest in integrating optical transceivers and other photonic components directly with electronic integrated circuits to facilitate high-bandwidth chip-to-chip and board-to-board interconnects. However, achieving efficient coupling between optical and electrical domains while maintaining compact form factors remains challenging with traditional packaging methods. Current solutions often necessitate separate optical and electrical assemblies, which are bulky and can introduce signal integrity issues at high data rates.

The description above is presented as a general overview of related art in this field and should not be construed as an admission that any of the information it contains constitutes prior art against the present patent application.

### SUMMARY

An embodiment of the present invention that is described herein provides an optoelectronic device, including (a) a substrate having (i) a surface, and (ii) a recess formed in the substrate that extends from the surface into the substrate, (b) an integrated circuit (IC) chip facing the surface of the substrate, (c) an optical connector mounted on the substrate, and (d) an optical chiplet embedded within the recess of the substrate, the optical chiplet being configured to exchange (i) optical signals with the optical connector, and (ii) electrical signals with the integrated circuit (IC) chip, and to convert between the optical signals and the electrical signals.

In some embodiments, the integrated circuit (IC) chip overlays at least a portion of the optical chiplet. In other embodiments, the optical chiplet includes (i) a photonic integrated circuit (PIC) configured to exchange the optical signals with the optical connector, (ii) an electrical integrated circuit (EIC) configured to exchange the electrical signals with the integrated circuit (IC) chip, and (iii) connections between the photonic integrated circuit (PIC) and the electrical integrated circuit (EIC). In yet other embodiments, the optoelectronic device further includes one or more optical waveguides (OWGs) embedded in the substrate and connecting between the optical chiplet and the optical connector, the optical waveguides (OWGs) being configured to convey the optical signals between the optical chiplet and the optical connector.

In some embodiments, the optical connector includes a pluggable optical connector configured to connect between (i) the optoelectronic device and (ii) one or more optical fibers. In other embodiments, the integrated circuit (IC) chip is mounted on a first section of the substrate, and the optical connector is mounted on (i) a second section of the surface, different from the first section, or (ii) an edge of the substrate. In yet other embodiments, the optoelectronic device further includes an interposer configured to exchange the electrical signals at least between (i) the optical chiplet and (ii) the integrated circuit (IC) chip, the interposer includes first and second opposing surfaces, the first surface mounted on the substrate and facing the optical chiplet and the integrated circuit (IC) chip is mounted on the second surface.

In some embodiments, the electrical signals include data signals and electrical power signals, and the optoelectronic device further includes first electrical connections and second electrical connections, each of the first electrical connections and the second electrical connections being formed in the substrate, the first electrical connections being configured to exchange the data signals between the (i) integrated circuit (IC) chip and (ii) the optical chiplet, and the second electrical connections being configured to exchange the electrical power signals between (i) a power source and (ii) the integrated circuit (IC) chip and the optical chiplet. In other embodiments, the substrate includes a glass interposer mounted on a package substrate configured to supply at least the electrical power signals. The glass interposer configured to exchange at least the electrical power signals between (i) the package substrate, and (ii) at least one of the optical chiplet and the integrated circuit (IC) chip. In yet other embodiments, the optoelectronic device further includes an additional integrated circuit (IC) chip facing the surface of the substrate, and an electrical die to die (DTD) interface configured to exchange additional data signals between the integrated circuit (IC) chip and the additional integrated circuit (IC) chip. At least one of the IC chip and the additional integrated circuit (IC) chip includes one or more (i) first data terminals configured to exchange the data signals with the optical chiplet, (ii) second data terminals configured to exchange the additional data signals with the electrical die to die (DTD) interface, and (iii) power terminals configured to exchange the electrical power signals and electrical ground signals with the second electrical connections.

There is additionally provided, in accordance with an embodiment of the present invention, a method for fabricating an optoelectronic device, the method includes receiving a substrate having (i) a surface, and (ii) a recess formed in the substrate and extended from the surface into the substrate. An optical chiplet is disposed within the recess of the substrate for being embedded within the substrate. An integrated circuit (IC) chip is mounted out of the substrate facing the surface of the substrate. An optical connector is mounted on the substrate. The optical chiplet being configured to: (a) exchange (i) optical signals with the optical connector, and (ii) electrical signals with the integrated circuit (IC) chip, and (b) convert between the optical signals and the electrical signals.

The present disclosure will be more fully understood from the following detailed description of the embodiments thereof, taken together with the drawings in which:

### BRIEF DESCRIPTION OF THE DRAWINGS

FIGS. 1 and 2 are schematic, sectional views of an optoelectronic device, in accordance with embodiments that are described herein;

FIG. 3 is a schematic sectional view of another configuration of an optoelectronic device, in accordance with another embodiment that is described herein; and

FIG. 4 is a flow chart that schematically illustrates a process for fabricating the optoelectronic device of FIGS. 1 and 2, in accordance with an embodiment that is described herein.

### DETAILED DESCRIPTION OF EMBODIMENTS

Embodiments of the present disclosure that are described herein provide techniques for improving optoelectronic devices by integrating substrate-embedded optical chiplets in interconnects of optoelectronic devices. The disclosed techniques improve intra-chip and intra-module electrical interconnects with optical interconnects.

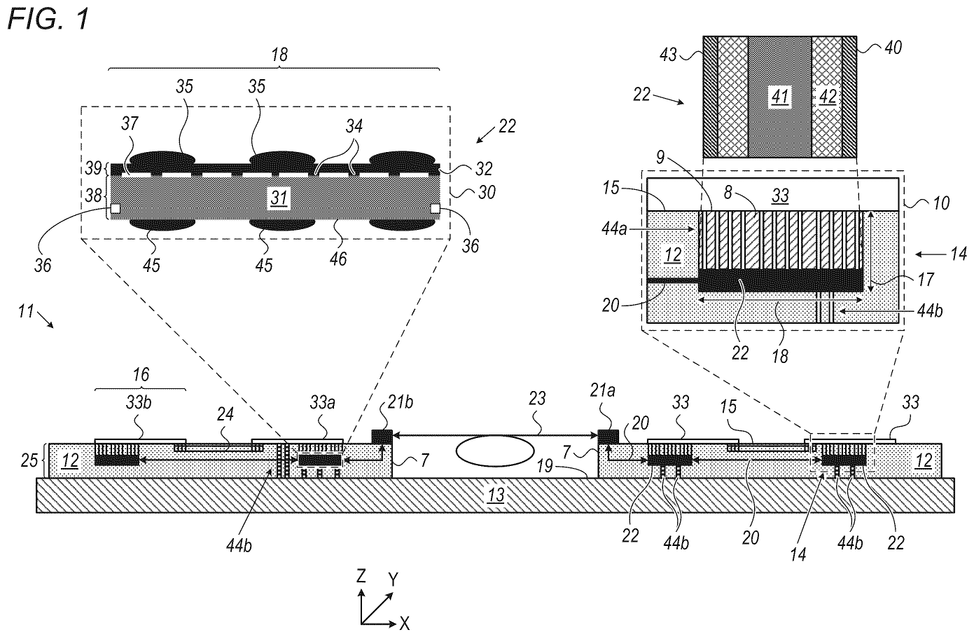

In some embodiments, an optoelectronic device comprises a substrate having a surface and one or more recesses or cavities, which are formed in the substrate. In the context of the present disclosure and in the claims, the terms recess, cavity and grammatical variations thereof are used interchangeably and refer to indentations or hollow spaces in the substrate. In the present example, the recesses or cavities extend from the surface into the substrate, and subsequently, filled with one or more components and/or layers of materials as described in detail in FIGS. 1-3 below. The substrate may be composed of glass (e.g., silicon dioxide) or any other suitable material, which is configured to contain (i) optical waveguides configured to convey optical signals, and (ii) electrical traces configured to conduct electrical signals. The substrate, recesses, optical waveguides and electrical traces are described in detail in FIGS. 1-3 below.

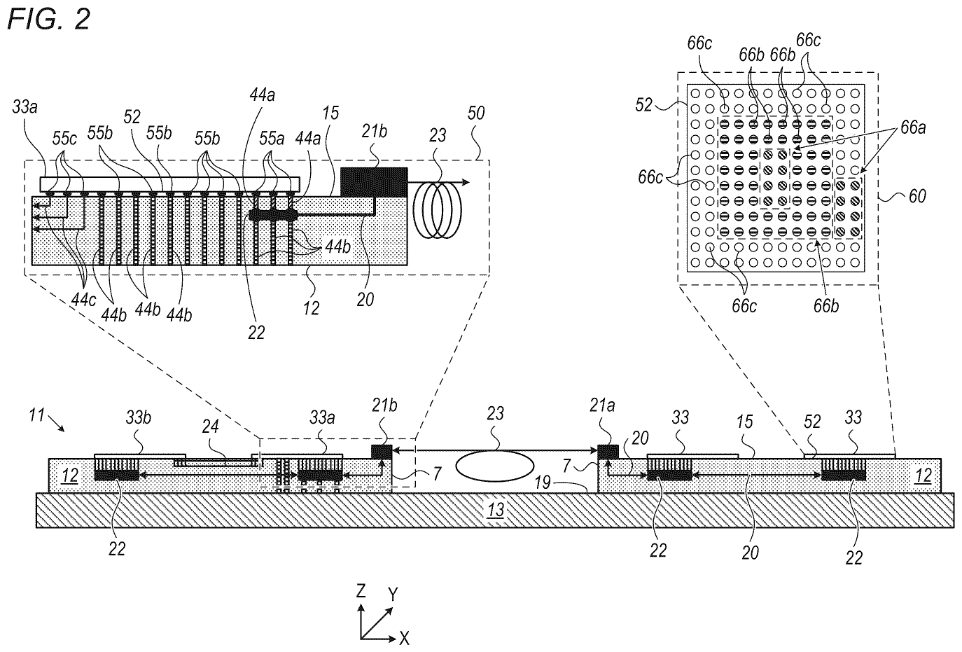

In some embodiments, the optoelectronic device comprises an integrated circuit (IC) chip facing the surface of the substrate. In the context of the present disclosure and in the claims, the terms “chip” and “die,” and grammatical variations thereof are used interchangeably and refer to any suitable active integrated-circuit device. The integrated circuit chip may comprise an application-specific integrated circuit (ASIC) or any other suitable IC configured to perform at least one of processing, storing, transmitting and receiving electrical signals. The optoelectronic device further comprises a pluggable optical connector (also referred to herein as an optical connector, for brevity) mounted on the surface or on the edge of the substrate as will be described in detail in the configuration shown in FIGS. 1 and 2 below. The optical connector is configured to connect with optical connections, such as optical fibers to exchange optical signals between the optoelectronic device and other optical components (e.g., external to the optoelectronic device) of an optical communication system.

In some embodiments, the optoelectronic device comprises an optical chiplet embedded within the recess of the substrate. The optical chiplet comprises (i) a photonic integrated circuit (PIC) configured to exchange optical signals with the optical connector, (ii) an electrical integrated circuit (EIC) configured to exchange electrical signals with the ASIC and other integrated circuit (IC) chips, and (iii) connections between the photonic integrated circuit (PIC) and the electrical integrated circuit (EIC). As such, the optical chiplet is configured to convert between the optical signals and the electrical signals, thereby enabling seamless communication between the optical components and the electrical processing components of the optoelectronic device. The structure and functionality of the optical chiplets are described in detail in FIG. 1 below.

In some embodiments, the optical chiplet is configured to exchange bidirectional (i) optical signals between optical components and other optical chiplets of the optoelectronic device, and (ii) electrical signals between electrical components and IC chips of the optoelectronic device. This allows for simultaneous transmission and reception of electrical signals and optical signals (i.e., full-duplex communication) to enhance the overall communication bandwidth of the optoelectronic device and between electronic devices of an optical communication system. Moreover, the optical chiplet is configured to translate (i) electrical signals to serial optical signals, and (ii) serial optical signals to the electrical signals, with or without an external laser source. It is noted that the electrical signals comprise parallel signals transmitted over wide buses and/or serial signals transmitted over narrower buses, and the serial optical signals being transmitted at speeds higher than that of the electrical signals. This flexibility allows for different configurations of the optoelectronic device, depending on the specific application requirements and system design constraints.

In some embodiments, the substrate comprises optical waveguides (OWGs) embedded within the substrate. These optical waveguides provide low-loss optical pathways for transmitting optical signals within the optoelectronic device, enabling efficient optical communication between different components. The combination of these features in the optoelectronic device allows for the integration of optical and electrical components in a compact form factor. In some embodiments, by embedding the optical chiplet within the substrate recess, the optoelectronic device is configured to have a reduced footprint and reduced length of the electrical connections, while maintaining high-performance optical and electrical signal processing capabilities.

In some embodiments, the glass substrate is configured to provide a suitable medium for the transmission of both optical signals and electrical signals. The ability of the glass structure to carry optical waveguides facilitates efficient routing of optical signals within the device, and the capability to support electrical signals provides the necessary electrical power and control connections for the various components. The integration of the photonic integrated circuit and electrical integrated circuit within the optical chiplet without consuming real estate in the IC chips and/or increasing the footprint of the substrate allows for efficient conversion between optical and electrical domains. This integration is configured to minimize signal degradation and latency that might occur when using separate optical and electrical components.

In some embodiments, the bidirectional optical communication capability of the optical chiplet is configured to enhance the overall bandwidth and flexibility of the optoelectronic device. This feature allows for simultaneous transmission and reception of optical signals (in a full-duplex manner), potentially doubling the communication capacity compared to unidirectional systems. The ability of the optical chiplet to operate with or without an external laser source provides design flexibility. In configurations where an external laser source is available, the optical chiplet can utilize this source for optical signal generation by modulating laser beams generated by the laser source. In cases where an external laser source is not available or desirable, the optical chiplet is configured to incorporate a laser source to maintain functionality in a self-contained manner.

In some embodiments, optical chiplet component embedding addresses the challenge of interfacing high-bandwidth, wide bus, electrical signals with serial optical transmission. With this technique, the distance traveled by the wide signal bus is greatly reduced. The reduced distance allows the bus to run faster and/or with thinner wires with reduced spacing between wires, and/or reduced drive strength allowing lower power designs that fit in a smaller footprint. The embedding of optical waveguides within the substrate facilitates the routing of optical signals between the optical chiplet, the optical connector, and potentially other optical components within the optoelectronic device. These waveguides provide low-loss transmission paths, maintaining signal integrity over the required distances within the optoelectronic device.

The disclosed techniques and the overall architecture of the optoelectronic device, with the embedded optical chiplet, integrated circuits, and optical waveguides, enable the creation of high-performance systems that leverage the benefits of both optical and electrical signal processing. This integration facilitates the development of compact, efficient, and high-bandwidth communication systems suitable for a wide range of applications in data centers, telecommunications, and other fields requiring advanced optoelectronic solutions.

The description above is presented as a general overview of embodiments of the present disclosure, which are described in detail herein.

FIGS. 1 and 2 are schematic, sectional views of an optoelectronic device 11, in accordance with embodiments that are described herein. Optoelectronic device 11 comprises a large number of elements associated with different aspects that are therefore separated into FIGS. 1 and 2. More specifically, insets 10, 30 and 40 of FIG. 1 describe embodiments related to optical chiplets 22, and insets 50 and 60 of FIG. 2 describe embodiments related to connectivity between components of optoelectronic device 11. Yet, it is important to note that optoelectronic device 11 comprises all the elements and features that will be described in detail in FIGS. 1 and 2 below.

Reference is now made to FIG. 1. In some embodiments, optoelectronic device 11 comprises two substrates 12 mounted on a surface 19 of a printed circuit board (PCB) 13. In a non-limiting example, PCB 13 has a width of about 500 mm along the X-axis and/or Y-axis, and each substrate 12 has a width of about 100 mm along the X-axis and/or Y-axis, and a thickness 25 (e.g., between about 2.6 mm and 3 mm). In some embodiments, substrate 12 has a substrate surface 15 and a recess 14 formed in the substrate 12 that extends from the surface 15 into the substrate 12.

In some embodiments, optoelectronic device 11 comprises pluggable optical connectors 21a and 21b (also referred to herein as optical connectors 21a and 21b, respectively). In the present example, optical connectors 21a and 21b are mounted on surface 15 of the two respective substrates 12. However, in other embodiments of the present disclosure, at least one of the optical connectors 21a or 21b may be mounted on an edge 7 of substrate 12. For instance, optical connectors 21a and 21b could be mounted on edge 7, aligned with optical chiplets 22 along the Z-axis, meaning connectors 21a or 21b would be in the same XY plane as the optical chiplets 22. Moreover, in the present example, optical chiplets 22 are aligned along the Z-axis at an approximately equal distance from surface 19 of PCB 13. However, in other embodiments, at least one of the optical chiplets 22 may be positioned, along the Z-axis relative to one or more of the other optical chiplets 22, at a different distance from surface 19 of PCB 13. In some embodiments, optical connectors 21a and 21b are configured to transmit and receive optical signals conveyed by an optical connector 23 (e.g., one or more optical fibers) connecting between connectors 21a and 21b. Optoelectronic device 11 further comprises one or more optical waveguides (OWGs) 20 embedded within at least one of and typically each substrate 12. In the present example, OWGs 20 are configured to transmit the optical signals within each substrate 12 of optoelectronic device 11, as will be described in more detail below. The arrowheads shown in OWGs 20 illustrate that OWGs 20 and optical chiplets 22 are configured to perform bidirectional transmission of the optical signals. In the present configuration, the OWGs 20, which provide optical connections between optical connectors 21a or 21b (mounted on surface 15) and optical chiplets 22, are bent (e.g., having an L-shape). Notably, mounting optical connectors 21a and 21b on edge 7, aligned with optical chiplets 22 along the Z-axis, enables the use of straight OWGs 20 between the optical connectors 21a or 21b and the respective optical chiplets 22. This alignment simplifies both the transmission of optical signals over these OWGs 20 and the fabrication process of the OWGs 20 in substrate 12.

In some embodiments, optoelectronic device 11 comprises multiple optical chiplets 22 embedded within respective recesses 14 formed in substrate 12. The features of recess 14 are shown in inset 10 and are described in detail below. Each optical chiplet 22 is configured to exchange the optical signals with other components of optoelectronic device 11 through the OWGs 20. In the present example, OWGs 20 are configured to convey the optical signals (i) between optical connectors 21 and optical chiplets 22, and (ii) between optical chiplets 22.

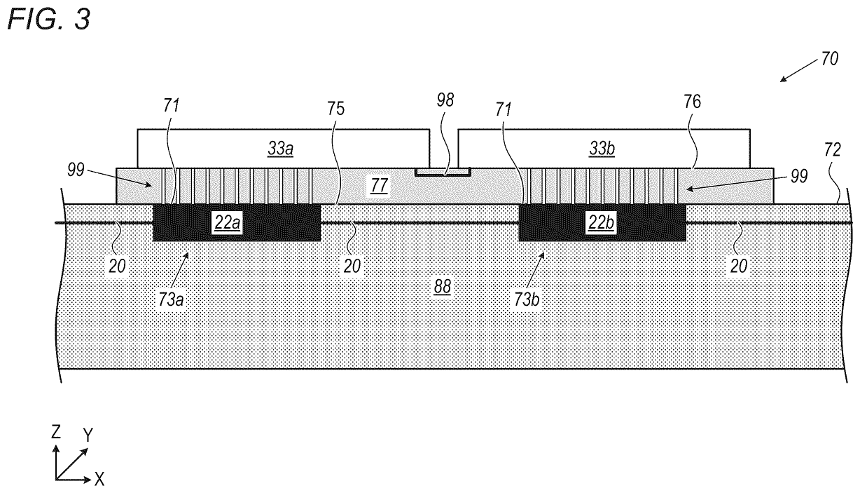

In some embodiments, optoelectronic device 11 comprises multiple integrated circuit (IC) chips, for example, application-specific integrated circuit devices (ASICs) 33. In the present example, each ASIC 33 is mounted on and facing surface 15 of substrate 12, but in other embodiments, ASIC 33 may not be directly mounted on surface 15, as will be described in the example of FIG. 3 below. It is noted that optoelectronic device 11 may comprise additional IC chips, such as memory devices, and processors (not shown) mounted on surface 15 and the embodiments described herein that are related to signals exchanged with ASICs 33 are applicable, mutatis mutandis, to the other sorts of IC chips.

In some embodiments, optoelectronic device 11 comprises an electrical die to die (DTD) interface 24 configured to conduct electrical signals between die to die blocks of ASIC 33a and ASIC 33b that are positioned on surface 15 over the ends of electrical DTD interface 24. In some embodiments, ASIC 33 overlays at least a portion of and typically the entire width of optical chiplet 22. This arrangement allows for efficient use of space within optoelectronic device 11. In the present example, ASIC 33b has a width 16, e.g., between about ten mm and 30 mm (typically about twenty-five millimeters), which typically extends beyond a smaller width 18 (shown in inset 10) of optical chiplet 22.

In some embodiments, substrate 12 is made of glass (e.g., silicon dioxide or any other suitable material) and is configured to contain (i) optical waveguides 20 configured to convey the optical signals within substrate 12, and (ii) electrical connections 44 formed within substrate 12, e.g., electrical connections 44a and 44c configured to conduct data signals and electrical connections 44b configured to conduct electrical power and electrical ground. Electrical connections 44 are described in detail in FIG. 2 below.

In some embodiments, the arrangement of components in optoelectronic device 11 allows for efficient integration of optical and electrical functionalities. By embedding the optical chiplet 22 within the recess 14 of the substrate 12 and positioning the ASIC 33 directly above the optical chiplet 22, optoelectronic device 11 achieves a compact form factor while maintaining high-performance communication (e.g., GHz-level data rates, and bandwidths in the order of terabits per second) of optical signals and electrical signals.

Reference is now made to inset 10 showing a detailed sectional view of recess 14, optical chiplet 22 and ASIC 33 overlaying optical chiplet 22. In some embodiments, recess 14 extends from surface 15 into substrate 12 and has a recess height 17 along the X-axis (e.g., between about 0.1 mm and 1.0 mm) and the aforementioned recess width 18 along the X-axis (e.g., about 3 mm or any other suitable width). In the present example, the size of recess 14 in the XY plane (of the XYZ coordinate system) is approximately similar to or slightly larger than that of optical chiplet 22. Optical chiplet 22 may be soldered into place or attached with a bonding material (e.g., epoxy). Recess 14 may be shaped in order to ensure alignment of optical chiplet 22 to OWGs 20. In such embodiments, optical chiplet 20 may be placed using an automated process (e.g. a pick and place) machine capable of ensuring alignment to the OWGs 20. In other embodiments, the size of recess 14 along the X-axis and/or Y-axis may be substantially larger than that of optical chiplet 22.

In some embodiments, optical chiplet 22, which is embedded within recess 14 of substrate 12, is optically connected with OWG 20. In the present example, optical chiplet 22 is configured to exchange the optical signals with another optical chiplet 22 and/or optical connector 21a (both shown in the general view of FIG. 1) over OWG 20. As described above, ASIC 33 faces surface 15 of substrate 12, and overlays (at least a portion of) optical chiplet 22.

In some embodiments, optoelectronic device 11 comprises electrical connections 44, also referred to herein as vias, formed along the Z-axis. In the example shown in inset 10, optoelectronic device 11 comprises a dielectric layer 8 deposited in recess 14 so that an upper surface 9 of dielectric layer 8 is approximately flush with surface 15 of substrate 12. Optoelectronic device 11 further comprises electrical connections 44a formed in dielectric layer 8 typically by (a) etching contact holes between (i) surface 9 of dielectric layer 8, and (ii) terminals 35 (shown in inset 30) formed on the upper surface of optical chiplet 22, and (b) filling the contact holes with copper or any other suitable electrically conductive layer. In such embodiments, electrical connections 44a are electrically coupled to optical chiplet 22 and ASIC 33 and are configured to conduct electrical signals between optical chiplet 22 and ASIC 33.

In some embodiments, optoelectronic device 11 further comprises electrical connections 44b produced by the etching and copper filling processes described above or using any other suitable processes. In some embodiments, electrical connections 44b are electrically coupled between (i) terminals 45 at the lower surface of optical chiplet 22 (shown in inset 30) and (ii) the upper surface 19 of PCB 13. In such embodiments, electrical connections 44b are configured to conduct electrical power and electrical ground between optical chiplet 22 and PCB 13. Electrical connections 44a and 44b are described in more detail in FIG. 2 below. This arrangement enables compact packaging of components of optoelectronic device 11 by positioning the optical and electronic connections embedded in substrate 12 without occupying lateral real estate on the surface of ASIC 33 and substrate 12.

Reference is now made to inset 40 showing a top view of an example configuration of the internal layout and key components of optical chiplet 22. In some embodiments, optical chiplet 22 comprises both photonic and electronic elements integrated into a single package and described in more detail in inset 30 below. In the present example, optical chiplet 22 comprises parallel signal transceivers 41 configured to handle multiple electrical signals simultaneously, enabling high-bandwidth data transfer between the optical chiplet and other electrical components, such as ASIC 33. Optical chiplet 22 further comprises one or more serializer/deserializer (SerDes) blocks 42 configured to convert (i) parallel data streams to serial data for optical transmission, and (ii) electrical serial data (e.g., converted from the optical signals) to parallel data streams.

In some embodiments, optical chiplet 22 further comprises a laser modulator 43 configured to encode electrical signals onto optical carriers to enable high-speed optical data transmission. In some embodiments, laser modulator 43 may operate in conjunction with other optical components to modulate optical signals in order to encode data for transmission. Laser modulator 43 is further configured to decode information carried by the optical signals, so as to generate the aforementioned electrical signals. Additionally, or alternatively, optical chiplet 22 may comprise an integrated laser source (not shown) so as to operate without an external laser source.

Reference is now made to inset 30 showing a detailed cross-sectional view of the optical chiplet 22 embedded within the recess 14 of substrate 12. In some embodiments, optical chiplet 22 comprises a layered structure with multiple functional components integrated into a compact package.

In some embodiments, optical chiplet 22 comprises a photonic integrated circuit (PIC) 31, which is a microchip that integrates multiple photonic components onto a single platform. Unlike electronic integrated circuits that use electrons to transmit information, PIC 31 is configured to use optical signals for communication and computation. PIC 31 may comprise photodetectors, modulators waveguides, and optionally laser source, and configured to detect, generate, transport, and process the optical signal. In the present example, PIC 31 comprises a substrate made from silicon (Si), indium phosphide (InP), germanium (Ge), silicon-germanium (SiGe) or any other suitable material, and has a thickness 38, e.g., between about 0.7 mm and 0.8 mm.

In some embodiments, optical chiplet 22 further comprises optical terminals 36 disposed between (i) PIC 31 and (ii) one or more optical waveguides (OWGs) 20. Optical terminals 36 are configured to exchange the optical signals between one or more OWGs 20 (shown in the general view of FIG. 1) and PIC 31. In some embodiments, optical terminals 36 may be implemented using waveguide-to-fiber couplers, such as grating couplers and/or edge couplers that may be integrated with PIC 31 and OWGs 20 using Planar Lightwave Circuit (PLC) technology or simply aligned such that the light from the OWG 20 is aimed directly into the PIC 31.

In some embodiments, optical chiplet 22 further comprises additional electrical terminals 45 disposed between (i) a surface 46 of optical chiplet 22, and (ii) electrical connections 44b extended between PCB 13 and one or more surfaces of recess 14, as shown in insets 10 and 50.

In some embodiments, optical chiplet 22 comprises an electrical integrated circuit (EIC) 32 positioned over PIC 31. EIC 32 may comprise electronic components such as transistors, interconnects, capacitors, resistors and logic gates, and has a thickness 39 (e.g., between about 25 μm and 75 μm). In some embodiments, EIC 32 is configured to interface with PIC 31 and with electronic IC chips, such as ASIC 33.

In some embodiments, optical chiplet 22 comprises a series of connections 34 formed between PIC 31 and EIC 32. Connections 34 may be implemented using hybrid bonds, micro-bumps, controlled collapse chip connection (C4) bumps or any other suitable technique. In the present configuration, connections 34 are spaced apart from one another by a spacing 37 having a width between about 0.8 μm and 1 μm. Connections 34 are configured to exchange electrical signals between PIC 31 and EIC 32 of optical chiplet 22.

In some embodiments, optical chiplet 22 comprises an array of terminals 35 (e.g., bumps) on the top surface of the EIC 32. These terminals 35 serve as the primary interface between the optical chiplet 22 and external components, such as electrical connections 44 and ASIC 33 shown in inset 10 and in the general view of FIG. 1.

In some embodiments, the layered structure of the optical chiplet 22, as depicted in inset 30, enables the integration of photonic and electronic functions within a single package. This architecture facilitates optical-to-electrical and electrical-to-optical signal conversion, as well as the signal processing and control functions required for optoelectronic device 11.

Reference is now made to inset 50, showing a sectional view of electrical and optical connections in a section of optoelectronic device 11. Inset 50 further illustrates the integration of ASIC 33 mounted on substrate 12 and overlays optical chiplet 22 embedded within substrate 12 as described in detail in inset 10 of FIG. 1 above.

In some embodiments, optoelectronic device 11 comprises multiple components embedded within substrate 12 and mounted on surface 15 of substrate 12 as will be described herein. In some embodiments, optical waveguides (OWGs) 20 are embedded within substrate 12 and configured to provide pathways for optical signal transmission within substrate 12, as described in FIG. 1 above. In the present example, an OWG 20 is connected between optical connector 21b and optical chiplet 22. OWG 20 is configured to exchange optical signals between the optical fibers of optical connection 23 and optical chiplet 22 via optical connector 21b.

In some embodiments, optoelectronic device 11 comprises (i) electrical connections 44a which are generally configured to conduct electrical signals between ASIC 33 and optical chiplet 22 but may also supply power from PCB 13 through device 11 to ASIC 33, (ii) electrical connections 44b generally configured to supply electrical power from PCB 13 (shown in the general view of FIGS. 1 and 2) to (a) ASIC 33 and (b) optical chiplet 22 but may also conduct electrical signals, and (iii) electrical connections 44c configured to conduct electrical signals between die to die blocks (not shown) of ASIC 33 and electrical DTD interface 24. It is noted that connections 44 serve different purposes, so that connections 44b are most often configured to provide electrical power and electrical ground, and connections 44a are most often configured to conduct electrical signals for data transmission, and 44c are always configured to conduct electrical signals for data transmission.

It is noted that optical signals are conveyed more efficiently compared to that of electrical signals conducted by connections 44a that may be implemented in electrical traces and through silicon vias. In the context of the present disclosure, the term efficiency refers to (i) less energy loss, and (ii) improved signal integrity due to less undesired charging and crosstalk between signals conducted by adjacent connections 44a. In some embodiments, embedding optical chiplet 22 within substrate 12 and positioning optical chiplet 22 directly beneath and in close proximity to ASIC 33 enables the transmission of data primarily via optical signals over OWGs 20, while utilizing short electrical connections 44a for conveying data over electrical signals along a brief path to ASIC 33. In essence, the disclosed techniques minimize the length of electrical connections 44a, thereby enhancing the quality of the signals transmitting data within optoelectronic device 11.

In some embodiments, optoelectronic device 11 comprises terminals 55 (implemented in bumps or other suitable terminals known in the art) disposed between surface 15 of substrate 12 and a surface 52 of ASIC 33. More specifically, (i) terminals 55a electrically coupled to electrical connections 44a and configured to conduct electrical signals between ASIC 33 and optical chiplet 22, (ii) terminals 55b electrically coupled to electrical connections 44b and configured to supply electrical power from PCB 13 to ASIC 33, and (iii) terminals 55c electrically coupled to electrical connections 44c and configured to conduct electrical signals between the aforementioned die to die blocks of ASIC 33 and electrical DTD interface 24.

The packaging configuration shown in the sectional view of inset 50 demonstrates the compact and integrated nature of optoelectronic device 11. This configuration illustrates how the optical chiplet 22, ASIC 33, and various electrical and optical components and connections are arranged and integrated with substrate 12 to create a high-performance and low-footprint optoelectronic device 11.

Optical chiplet 22 is further configured to convert between the optical signals exchanged with the optical connector and the electrical signals exchanged with ASIC 33. This conversion capability enables optoelectronic device 11 to interface between optical and electrical domains.

Reference is now made to inset 60 showing a bottom view of surface 52 of ASIC 33. As described above, surface 52 faces substrate 12 and optical chiplet 22.

In some embodiments, surface 52 comprises multiple types of connections 66 (e.g., terminals such as pads or bumps) arranged in specific patterns and described in detail below. Connections 66 are configured to exchange electrical signals (e.g., data signals and electrical power and ground) between ASIC 33 and other components of optoelectronic device 11. In some embodiments, connections 66 may be used instead of or in addition to terminals 55 shown in inset 50 and described in detail above.

In some embodiments, connections 66a are mounted on surface 52, positioned in one or more regions facing one or more respective optical chiplets 22, and configured to interface with optical chiplet 22 via connections 44a. In an embodiment, connections 66a may be arranged in a grid pattern (or any other suitable array), allowing for high-density signal transmission between ASIC 33 and one or more optical chiplets 22.

In some embodiments, power/ground connections 66b are disposed on surface 52 and, in the present example, are distributed at the center of surface 52. The power/ground connections 66b provide the necessary electrical power and grounding for ASIC 33 and may also contribute to signal integrity by creating a stable electrical environment.

In some embodiments, surface 52 has serial connections 66c mounted thereon. In the present example, connections 66c are distributed around the perimeter of surface 52, forming a ring-like arrangement surrounding connections 66a and 66b. The serial connections 66c may be used for high-speed data transmission and thereby facilitates SerDes (Serializer/Deserializer) functionality and/or die-to-die (D2D) communication as described in the example of inset 50 above.

In some embodiments, the arrangement of connections 66a, 66b and 66c on surface 52 is optimized to minimize signal path lengths between ASIC 33 and other components of optoelectronic device 11, such as optical chiplet 22 and electrical DTD interface 24. This optimization may contribute to reduced latency and improved signal integrity of the signals conveyed in optoelectronic device 11.

In some embodiments, the density and distribution of connections 66a, 66b and 66c on surface 52 may vary depending on the specific requirements of the optoelectronic device 11. For example, areas requiring higher bandwidth may have a higher density of connections 66, while areas with lower bandwidth requirements may have a lower density. The bottom view of surface 52 illustrates the complex interconnect structure required to integrate ASIC 33 with optical chiplet 22 and other components of the optoelectronic device 11. This intricate arrangement of connections enables the high-performance operation of the device, allowing for efficient communication between electrical and optical domains of optoelectronic device 11.

FIG. 3 is a schematic sectional view of an optoelectronic device 70, in accordance with another embodiment that is described herein. In some embodiments, optoelectronic device 70 may be mounted on a circuit board substrate, such as the PCB 13 shown in FIGS. 1 and 2 above, or on any other suitable substrate. This circuit board substrate is configured to supply power to the optoelectronic device 70 and/or to exchange data with optoelectronic device 70.

In some embodiments, optoelectronic device 70 comprises a substrate 88 that may (i) have the same features as substrate 12, or (ii) be a section of substrate 12 in the optoelectronic device 11 shown in FIGS. 1 and 2 above. In other embodiments, substrate 88 may comprise any other suitable material and/or may have any suitable thickness and width other than that of substrate 12 as described in FIGS. 1 and 2 above.

In some embodiments, optoelectronic device 70 comprises optical chiplets 22a and 22b embedded in respective recesses 73a and 73b formed in substrate 88. Moreover, substrate 88 comprises optical waveguides (OWGs) 20 embedded in substrate 88 and configured to convey optical signals between optical chiplets 22a and 22b.

In some embodiments, an upper surface 71 of optical chiplets 22a and 22b is approximately flush with an upper surface 72 of substrate 88. In other embodiments, at least one of recesses 73a and 73b may be deeper (along the Z-axis) than the thickness of at least one of optical chiplets 22a and 22b, respectively, causing surface 71 to be positioned lower than surface 72 along the Z-axis. In such embodiments, at least one of optical chiplets 22a and 22b may be fully embedded in substrate 88 so that (i) a dielectric layer (not shown) may be deposited over surface 71 of the respective optical chiplet 22, and (ii) the upper surface of the dielectric layer is approximately flush with surface 72 of substrate 88. It should be noted that a similar configuration and its fabrication process are described in more detail in inset 10 of FIG. 1 above.

In some embodiments, optoelectronic device 70 comprises an interposer 77 having a lower surface 75 mounted on surface 72 of substrate 88, and an upper surface 76 opposite lower surface 75. The interposer 77 allows finer routing details (thinner wires and spaces) than that of substrate 88. Interposer 77 may be formed on silicon, redistribution layers on organic substrate, glass, or any other suitable material or combination of materials. In some embodiments, ASICs 33a and 33b are mounted on surface 76 and are electrically interconnected using connections 98 (also referred to herein as via connections) that may be embedded in interposer 77 or formed over surface 76. Connections 98 may have a structure similar to that of electrical DTD interface 24 shown in FIG. 1 above.

In some embodiments, interposer 77 has vias, such as but not limited to Through-Silicon Vias (TSVs) 99, formed along the Z-axis between surfaces 75 and 76. The TSVs 99 (or other types of vias) of interposer 77 are configured to exchange electrical signals between (i) optical chiplet 22a and ASIC 33a, and (ii) optical chiplet 22b and ASIC 33b. In this example configuration, interposer 77 is constructed from a silicon substrate and may have a high density of interconnects 98 and/or TSVs 99 to support the exchange of high-bandwidth communication signals between ASICs 33a and 33b as well as between the ASICs 33 and respective optical chiplets 22. As described above, the communication between optical chiplets 22a and 22b is obtained through optical signals transmitted over the OWGs 20 described above. It is important to note that the speed and efficiency of transmitting optical signals generally surpass that of electrical signals. Consequently, at least some of the data intended for ASIC 33b may be transmitted as optical signals from optical chiplet 22a to optical chiplet 22b and subsequently converted to electrical signals in optical chiplet 22b and transmitted from optical chiplet 22b, via TSVs 99, to ASIC 33b.

In other embodiments, interposer 77 of optoelectronic device 70 may be implemented, with necessary changes having been made, in optoelectronic device 11. For example, interposer 77 may be implemented in optoelectronic device 11 between a section of substrates 12 and one or more ASICs 33.

The configurations of optoelectronic devices 11 and 70 are provided by way of example, in order to illustrate certain data communication challenges and problems addressed by embodiments of the present invention and to demonstrate the application of these embodiments in enhancing the performance of such optoelectronic devices operating in data centers and artificial intelligence applications being operated within cloud computing and other high-speed communication systems as well as other high-performance computing applications. Embodiments of the present invention, however, are by no means limited to this specific sort of example configurations, and the principles described herein may similarly be applied to other types of optoelectronic devices operating in any other high-performance computing environments.

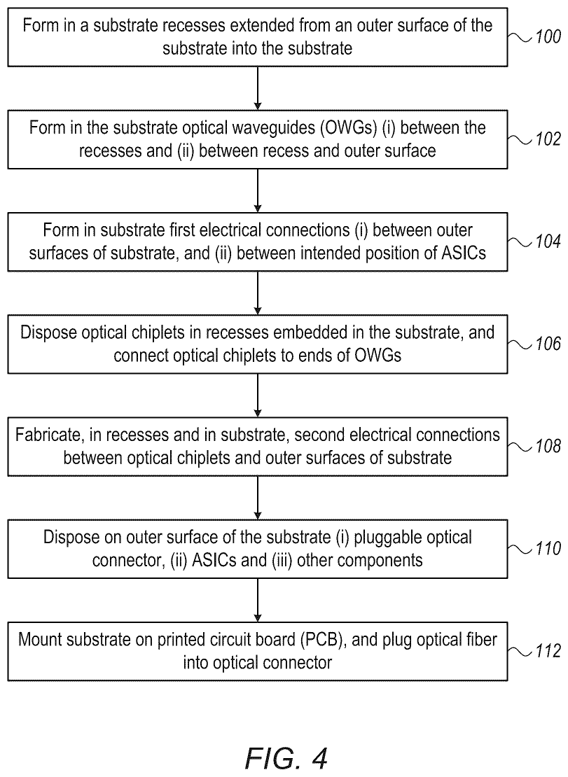

FIG. 4 is a flow chart that schematically illustrates a method for fabricating electronic device 11, in accordance with an embodiment that is described herein.

The method begins at a recess formation operation 100, with etching in substrate 12 one or more recesses 14 extended from surface 15 into the bulk of substrate 12, as shown and described in detail in FIG. 1 above.

At a waveguide formation operation 102, optical waveguides (OWGs) 20 are formed in substrate 12 to convey the optical signals. The OWGs 20 may be formed (i) between the recesses 14 and (ii) between recess 14 and outer surface 15 of substrate 12, as described in detail in FIG. 1 above.

At a first electrical connection formation operation 104, electrical connections 44b are formed (i) between the outer surfaces of substrate 12, e.g., between surface 15 of substrate 12 and surface 19 of PCB 13, and (ii) between the lower surfaces of substrate 12 and recess 14, which is the intended position of optical chiplet 22. Moreover, the connections (e.g., electrical traces) of electrical DTD interface 24 are being formed within substrate 12 or over surface 15 of surface 12, as described in FIGS. 1-3 above.

At a chiplet and terminal disposing operation 106, optical chiplets 22, electrical terminals 35 and 45, and optical terminals 36 are disposed in respective recesses 14, and thereby being embedded within substrate 12. Moreover, optical chiplets 22 are optically connected with OWGs 20 using one or more optical terminals 36 that are disposed between (i) PIC 31 and (ii) one or more respective optical waveguides (OWGs) 20, as shown in inset 30 and described in detail in FIG. 1 above.

At a second electrical connection formation operation 108, dielectric layer 8 is formed in recesses 14 and electrical connections 44a are formed through dielectric layer 8 along the Z-axis between surface 9 and terminals 35 coupled to optical chiplet 22, as shown in insets 10 and 30 and described in detail in FIG. 1 above.

At a component mounting operation 110, pluggable optical connectors 21a and 21b, ASICs 33, 33a and 33b and optionally, other components are mounted on surface 15 of substrate 12. The other components may comprise (i) active IC chips (e.g., processors, controllers and high bandwidth memory comprising stacked memory chips), and (ii) passive components such as capacitors, resistors and inductors. In some embodiments, interposer 77 of FIG. 3 may be disposed between (i) substrate 12 (shown as substrate 88 that may be a section of substrate 12, as described in FIG. 3 above) and (ii) at least ASICs 33a and 33b. In some embodiments, interposer 77 is typically made from a silicon wafer having a diameter of about 200 mm or 300 mm, and one or more interposers 77 may be disposed on the entire surface of substrate 12 or 88 and have the other aforementioned components disposed on surface 76 of interposer(s) 77.

At a substrate mounting operation 112 that concludes the method, substrate 12 is mounted on surface 19 of PCB 13 and the optical fibers of optical connection 23 are plugged into optical connectors 21a and 21b, as described in detail in FIG. 1 above.

It is noted that a typical process for fabricating optoelectronic device 11 may comprise over one thousand different operations. Thus, the fabrication method described in FIG. 4 is highly simplified and includes hundreds of operations that have been omitted from the description above for the sake of conceptual clarity.

In addition to the embodiments described in operation 110 above, the method of FIG. 4 is applicable for fabricating optoelectronic device 70, for example, by disposing interposer 77 between substrate 88 and one or more ASICs 33 as described in more detail in FIG. 3 above.

It is noted that the embodiments described above are cited by way of example, and that the present invention is not limited to what has been particularly shown and described hereinabove. Rather, the scope of the present invention comprises both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. An optoelectronic device, comprising:
a substrate having (i) a surface, and (ii) a recess formed in the substrate that extends from the surface into the substrate;
an integrated circuit (IC) chip facing the surface of the substrate;
an optical connector mounted on the substrate; and
an optical chiplet embedded within the recess of the substrate, the optical chiplet being configured to:
exchange (i) optical signals with the optical connector, and (ii) electrical signals with the integrated circuit (IC) chip, and
convert between the optical signals and the electrical signals.

2. The optoelectronic device according to claim 1, wherein the integrated circuit (IC) chip overlays at least a portion of the optical chiplet.

3. The optoelectronic device according to claim 1, wherein the optical chiplet comprises (i) a photonic integrated circuit (PIC) configured to exchange the optical signals with the optical connector, (ii) an electrical integrated circuit (EIC) configured to exchange the electrical signals with the integrated circuit (IC) chip, and (iii) connections between the photonic integrated circuit (PIC) and the electrical integrated circuit (EIC).

4. The optoelectronic device according to claim 1, further comprising one or more optical waveguides (OWGs) embedded in the substrate and connecting between the optical chiplet and the optical connector, the optical waveguides (OWGs) being configured to convey the optical signals between the optical chiplet and the optical connector.

5. The optoelectronic device according to claim 1, wherein the optical connector comprises a pluggable optical connector configured to connect between (i) the optoelectronic device and (ii) one or more optical fibers.

6. The optoelectronic device according to claim 1, wherein the integrated circuit (IC) chip is mounted on a first section of the substrate, and the optical connector is mounted on (i) a second section of the surface, different from the first section, or (ii) an edge of the substrate.

7. The optoelectronic device according to claim 1, further comprises an interposer configured to exchange the electrical signals at least between (i) the optical chiplet and (ii) the integrated circuit (IC) chip, the interposer comprises first and second opposing surfaces, the first surface mounted on the substrate and facing the optical chiplet and the integrated circuit (IC) chip is mounted on the second surface.

8. The optoelectronic device according to claim 1, wherein:
the electrical signals comprise data signals and electrical power signals, and
the optoelectronic device further comprises first electrical connections and second electrical connections, each of the first electrical connections and the second electrical connections being formed in the substrate, the first electrical connections being configured to exchange the data signals between the (i) integrated circuit (IC) chip and (ii) the optical chiplet, and the second electrical connections being configured to exchange the electrical power signals between (i) a power source and (ii) the integrated circuit (IC) chip and the optical chiplet.

9. The optoelectronic device according to claim 8, wherein the substrate comprises a glass interposer mounted on a package substrate configured to supply at least the electrical power signals, the glass interposer configured to exchange at least the electrical power signals between (i) the package substrate, and (ii) at least one of the optical chiplet and the integrated circuit (IC) chip.

10. The optoelectronic device according to claim 8, further comprising an additional integrated circuit (IC) chip facing the surface of the substrate, and an electrical die to die (DTD) interface configured to exchange additional data signals between the integrated circuit (IC) chip and the additional integrated circuit (IC) chip, and wherein at least one of the IC chip and the additional integrated circuit (IC) chip comprises one or more (i) first data terminals configured to exchange the data signals with the optical chiplet, (ii) second data terminals configured to exchange the additional data signals with the electrical die to die (DTD) interface, and (iii) power terminals configured to exchange the electrical power signals and electrical ground signals with the second electrical connections.

11. A method for fabricating an optoelectronic device, the method comprising:
receiving a substrate having (i) a surface, and (ii) a recess formed in the substrate and extended from the surface into the substrate;
disposing, within the recess of the substrate, an optical chiplet being embedded within the substrate mounting, out of the substrate, an integrated circuit (IC) chip facing the surface of the substrate; and
mounting, on the substrate, an optical connector;
wherein the optical chiplet being configured to:
exchange (i) optical signals with the optical connector, and (ii) electrical signals with the integrated circuit (IC) chip, and
convert between the optical signals and the electrical signals.

12. The method according to claim 11, wherein disposing the integrated circuit (IC) chip comprises disposing the integrated circuit (IC) chip to overlay at least a portion of the optical chiplet.

13. The method according to claim 11, wherein disposing the optical chiplet comprises disposing (i) a photonic integrated circuit (PIC) configured to exchange the optical signals with the optical connector, (ii) an electrical integrated circuit (EIC) configured to exchange the electrical signals with the integrated circuit (IC) chip, and (iii) connections between the photonic integrated circuit (PIC) and the electrical integrated circuit (EIC).

14. The method according to claim 11, further comprising embedding one or more optical waveguides (OWGs) in the substrate and connecting the embedded one or more optical waveguides (OWGs) between the optical chiplet and the optical connector, the optical waveguides (OWGs) being configured to convey the optical signals between the optical chiplet and the optical connector.

15. The method according to claim 11, wherein mounting the optical connector comprises mounting a pluggable optical connector configured to connect between (i) the optoelectronic device and (ii) one or more optical fibers.

16. The optoelectronic device according to claim 11, wherein mounting the integrated circuit (IC) chip comprises mounting the integrated circuit (IC) chip on a first section of the substrate, and mounting the optical connector comprises mounting the optical connector on (i) a second section of the surface, different from the first section, or (ii) an edge of the substrate.

17. The method according to claim 11, further comprising disposing, between at least the substrate and the integrated circuit (IC) chip, an interposer configured to exchange the electrical signals at least between (i) the optical chiplet and (ii) the integrated circuit (IC) chip, the interposer comprises first and second opposing surfaces, further comprising mounting, on the substrate, the first surface facing the optical chiplet, and mounting the integrated circuit (IC) chip on the second surface.

18. The method according to claim 11, wherein:
the electrical signals comprise data signals and electrical power signals,
further comprising, (a) forming in the substrate first electrical connections and second electrical connections, (b) connecting one or more of the first electrical connections between (i) the integrated circuit (IC) chip and (ii) the optical chiplet, and (c) connecting one or more of the second electrical connections between (i) a power source and (ii) at least one of the integrated circuit (IC) chip and the optical chiplet.

19. The method according to claim 18, wherein receiving the substrate comprises receiving a glass interposer, and mounting the glass interposer on a package substrate configured to supply at least the electrical power signals, the glass interposer configured to exchange at least the electrical power signals between (i) the package substrate, and (ii) at least one of the optical chiplet and the integrated circuit (IC) chip.

20. The method according to claim 18, further comprising mounting, out of the substrate, an additional integrated circuit (IC) chip facing the surface of the substrate, and forming, between the integrated circuit (IC) chip and the additional integrated circuit (IC) chip, an electrical die to die (DTD) interface configured to exchange additional data signals between the integrated circuit (IC) chip and the additional integrated circuit (IC) chip, and wherein at least one of the IC chip and the additional integrated circuit (IC) chip comprises one or more (i) first data terminals configured to exchange the data signals with the optical chiplet, (ii) second data terminals configured to exchange the additional data signals with the electrical die to die (DTD) interface, and (iii) power terminals configured to exchange the electrical power signals and electrical ground signals with the second electrical connections.
